(19) United States
(12) Patent Application Publication
(10) Pub. No.: US 2023/0105252 A1
(43) Pub. Date: Apr. 6, 2023

(54) INTERPOSER AND SUBSTRATE MODULE

(71) Applicant: Murata Manufacturing Co., Ltd., Nagaokakyo-shi (JP)

(72) Inventor: Yuichi MARUYAMA, Nagaokakyo-shi (JP)

(21) Appl. No.: 18/080,786

(22) Filed: Dec. 14, 2022

Related U.S. Application Data
(63) Continuation of application No. PCT/JP2021/019129, filed on May 20, 2021.

(30) Foreign Application Priority Data
Jul. 2, 2020 (JP) 2020-114863

(51) Int. Cl. H01B 5/16; H01R 12/61; H01R 4/04; H05K 1/02; H01R 12/69

(52) U.S. Cl. CPC H01B 5/16; H01R 12/613; H01R 4/04; H05K 1/0237; H01R 12/69; H01P 3/08

(57) ABSTRACT

In an interposer, metal bodies are included in a resin layer and separated from each other. A dimension of each of the metal bodies in an upward-downward direction is greater than a dimension of each of the plurality of metal bodies in a direction orthogonal to the upward-downward direction. At least one of the metal bodies is located in a first electrode and at least one of the plurality of metal bodies is located in a second electrode to electrically couple together the first electrode and the second electrode.

### CROSS REFERENCE TO RELATED APPLICATIONS

This application claims the benefit of priority to Japanese Patent Application No. 2020-114863 filed on Jul. 2, 2020 and is a Continuation Application of PCT Application No. PCT/JP2021/019129 filed on May 20, 2021. The entire contents of each application are hereby incorporated herein by reference.

### BACKGROUND OF THE INVENTION

### 1. Field of the Invention

The present invention relates to interposers that couple together first and second substrates, and to substrate modules.

### 2. Description of the Related Art

One known invention related to conventional interposers is an anisotropic conductive film described in Japanese Unexamined Patent Application Publication No. 2020-53403. This anisotropic conductive film has a structure in which a plurality of conductive particles are dispersed in an insulating resin layer. The anisotropic conductive film couples together a first substrate including a first electrode and a second substrate including a second electrode. Specifically, the first electrode is disposed on a lower main surface of the first substrate. The first substrate is joined to an upper main surface of an insulating resin layer. The second electrode is disposed on an upper main surface of the second substrate. The second substrate is joined to a lower main surface of the insulating resin layer. During joining, the first electrode enters the insulating resin layer through the upper main surface thereof in the downward direction. The second electrode enters the insulating resin layer through the lower main surface thereof in the upward direction. The first electrode and the second electrode then hold the conductive particles therebetween in the upward-downward direction. As a result, the first electrode and the second electrode are electrically coupled together through the conductive particles.

### SUMMARY OF THE INVENTION

It may be difficult to electrically couple together the first electrode and the second electrode using the anisotropic conductive film described in Japanese Unexamined Patent Application Publication No. 2020-53403. More specifically, there are cases where the first electrode does not protrude downward from the lower main surface of the first substrate. That is, there are cases where the first electrode is recessed from the lower main surface of the first substrate. Similarly, there are cases where the second electrode does not protrude upward from the upper main surface of the second substrate. That is, there are cases where the second electrode is recessed from the upper main surface of the second substrate. In such cases, insufficient pressure may be applied between the first electrode and the second electrode. This may result in the conductive particles not being held between the first electrode and the second electrode. Thus, it may be difficult to electrically couple together the first electrode and the second electrode using the anisotropic conductive film described in Japanese Unexamined Patent Application Publication No. 2020-53403.

Accordingly, preferred embodiments of the present invention provide interposers and substrate modules that each allow a first electrode of a first substrate and a second electrode of a second substrate to be easily coupled together.

An interposer according to a first aspect of a preferred embodiment of the present invention is an interposer to couple together a first substrate and a second substrate, the first substrate including a first-substrate upper main surface and a first-substrate lower main surface and including a first electrode that is a portion of the first-substrate lower main surface, the second substrate including a second-substrate upper main surface and a second-substrate lower main surface and including a second electrode that is a portion of the second-substrate upper main surface, the interposer including a resin layer including a resin-layer upper main surface to be joined to the first-substrate lower main surface and a resin-layer lower main surface to be joined to the second-substrate upper main surface, and a plurality of metal bodies arranged in the resin layer so as to be separated from each other, a dimension of each of the plurality of metal bodies in an upward-downward direction being greater than a dimension of each of the plurality of metal bodies in a direction orthogonal to the upward-downward direction, wherein at least one of the plurality of metal bodies is located in the first electrode and at least one of the plurality of metal bodies is located in the second electrode to electrically couple together the first electrode and the second electrode.

An interposer according to a second aspect of a preferred embodiment of the present invention includes a resin layer including a resin-layer upper main surface and a resin-layer lower main surface, and a plurality of metal bodies arranged in the resin layer so as to be separated from each other, a dimension of each of the plurality of metal bodies in an upward-downward direction being greater than a dimension of the plurality of metal bodies in a direction orthogonal to the upward-downward direction and about one half of a thickness of the resin layer in the upward-downward direction.

The definitions of the terms in the present specification will be described below. In the present specification, “axis or member extending in the forward-backward direction” does not necessarily refer only to an axis or member parallel to the forward-backward direction. “Axis or member extending in the forward-backward direction” refers to an axis or member inclined within the range of about ±45° with respect to the forward-backward direction. Similarly, “axis or member extending in the upward-downward direction” refers to an axis or member inclined within the range of about ±45° with respect to the upward-downward direction. “Axis or member extending in the leftward-rightward direction” refers to an axis or member inclined within the range of about ±45° with respect to the leftward-rightward direction.

In the following description, “first member” to “third member” refer to members or the like included in an interposer or a substrate module. In the present specification, the individual portions of the first member are defined as follows unless otherwise specified. “Front portion of the first member” refers to a front half of the first member. “Back portion of the first member” refers to a back half of the first member. “Left portion of the first member” refers to a left half of the first member. “Right portion of the first member” refers to a right half of the first member. “Upper portion of the first member” refers to an upper half of the first member. “Lower portion of the first member” refers to a lower half of the first member. “Front end of the first member” refers to an end of the first member in the forward direction. “Back end of the first member” refers to an end of the first member in the backward direction. “Left end of the first member” refers to an end of the first member in the leftward direction. “Right end of the first member” refers to an end of the first member in the rightward direction. “Upper end of the first member” refers to an end of the first member in the upward direction. “Lower end of the first member” refers to an end of the first member in the downward direction. “Front end portion of the first member” refers to the front end and its vicinity of the first member. “Back end portion of the first member” refers to the back end and its vicinity of the first member. “Left end portion of the first member” refers to the left end and its vicinity of the first member. “Right end portion of the first member” refers to the right end and its vicinity of the first member. “Upper end portion of the first member” refers to the upper end and its vicinity of the first member. “Lower end portion of the first member” refers to the lower end and its vicinity of the first member.

When “first member” and “second member” are defined as any two members in the present specification, the meaning of the relationship between any two members is as follows. In the present specification, “the first member is supported by the second member” includes a situation where the first member is attached to the second member so as not to be movable relative to the second member (i.e., is fixed) and a situation where the first member is attached to the second member so as to be movable relative to the second member. In addition, “the first member is supported by the second member” includes both a situation where the first member is directly attached to the second member and a situation where the first member is attached to the second member with a third member interposed therebetween.

In the present specification, “the first member is fixed to the second member” includes a situation where the first member is attached to the second member so as not to be movable relative to the second member, and does not include a situation where the first member is attached to the second member so as to be movable relative to the second member. In addition, “the first member is fixed to the second member” includes both a situation where the first member is directly attached to the second member and a situation where the first member is attached to the second member with a third member interposed therebetween.

In the present specification, “the first member and the second member are electrically coupled together” refers to a situation where a direct current can flow between the first member and the second member. Therefore, the first member and the second member may be, but need not be, in contact with each other. When the first member and the second member are not in contact with each other, a conductive third member is disposed between the first member and the second member.

The interposers and substrate modules according to preferred embodiments of the present invention allow a first electrode of a first substrate and a second electrode of a second substrate to be easily coupled together.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a top view of an electronic device 1 including a substrate module 10.

FIG. 2 is an exploded perspective view of the substrate module 10.

FIG. 3 is a sectional view, taken along line A-A, of the substrate module 10.

FIG. 4 illustrates a top view and a sectional view, taken along line B-B, of an interposer 16.

FIG. 5 is a sectional view of a metal member 20.

FIG. 6 is a sectional view of the substrate module 10 during fabrication.

### DETAILED DESCRIPTION OF THE PREFERRED EMBODIMENTS

### Preferred Embodiments

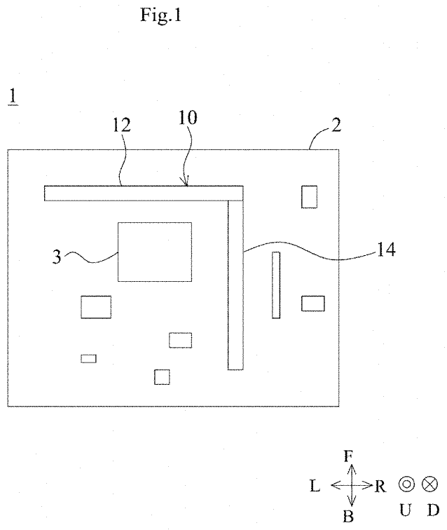

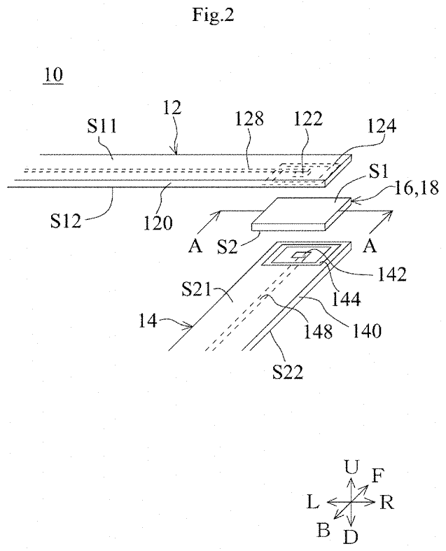

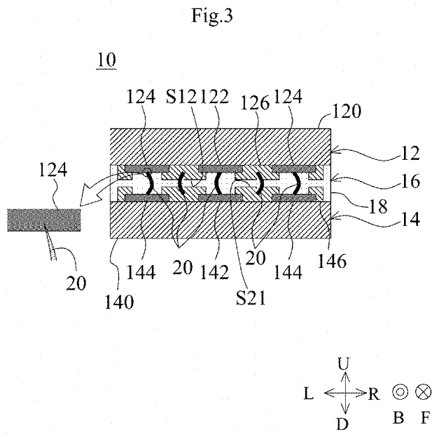

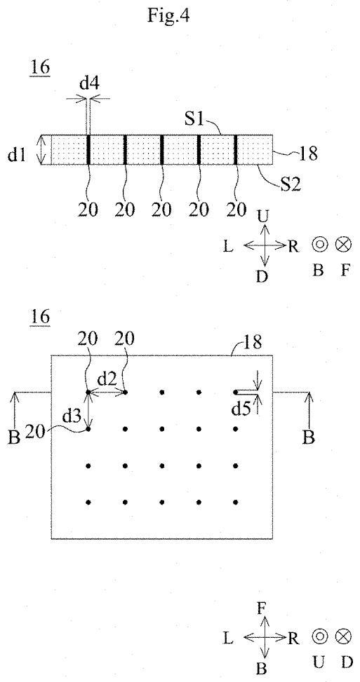

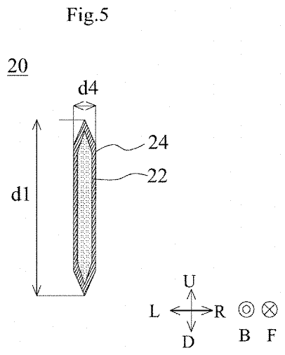

A substrate module 10 including an interposer 16 according to a preferred embodiment of the present invention will be described below with reference to the drawings. FIG. 1 is a top view of an electronic device 1 including the substrate module 10. Of a plurality of electronic components 3 in FIG. 1, only a representative electronic component 3 is denoted by a reference numeral. FIG. 2 is an exploded perspective view of the substrate module 10. FIG. 3 is a sectional view, taken along line A-A, of the substrate module 10. FIG. 4 illustrates a top view and a sectional view, taken along line B-B, of the interposer 16. FIG. 5 is a sectional view of a metal member 20 (metal body).

In the present specification, directions are defined as follows. The upward-downward direction is defined as the direction in which the first substrate 12, the interposer 16, and the second substrate 14 are stacked together. The leftward-rightward direction is defined as the direction in which the first substrate 12 extends as viewed in the upward-downward direction. The forward-backward direction is defined as the direction in which the second substrate 14 extends as viewed in the upward-downward direction. The upward-downward direction, the leftward-rightward direction, and the forward-backward direction are orthogonal to each other. The definitions of the directions in the present specification are merely illustrative. Therefore, the directions in the present specification need not be identical to those during actual use of the substrate module 10. In addition, the upward-downward direction in the drawings may be inverted. Similarly, the leftward-rightward direction in the drawings may be inverted. The forward-backward direction in the drawings may be inverted.

The electronic device 1 is, for example, a portable communication terminal such as a smartphone. As illustrated in FIG. 1, the electronic device 1 includes a circuit board 2, a plurality of electronic components 3, and a substrate module 10. The circuit board 2 is, for example, a motherboard. The circuit board 2 has a plate shape. Therefore, the circuit board 2 has an upper main surface and a lower main surface. Electrical circuits are disposed on the surfaces of and inside the circuit board 2.

The plurality of electronic components 3 are, for example, electronic chip components or semiconductor integrated circuits. The plurality of electronic components 3 are mounted on the upper main surface of the circuit board 2.

The substrate module 10 is a radio-frequency signal transmission line that electrically couples together two electrical circuits in the electronic device 1. In this preferred embodiment, the substrate module 10 electrically couples together two positions on the circuit board 2. As illustrated in FIG. 2, the substrate module 10 includes a first substrate 12, a second substrate 14, and an interposer 16.

The first substrate 12 extends in the leftward-rightward direction (a first direction orthogonal to the upward-downward direction). The first substrate 12 has a plate shape. Therefore, the first substrate 12 has a first-substrate upper main surface S11 and a first-substrate lower main surface S12.

As illustrated in FIGS. 2 and 3, the first substrate 12 includes a body 120, a signal electrode 122, a ground electrode 124, a resist layer 126, and a first signal conductor layer 128. The body 120 has a structure including a plurality of insulator layers stacked together in the upward-downward direction. The body 120 is formed of an insulating material. The insulating material for the body 120 is, for example, a liquid crystal polymer (LCP) or polyimide.

The signal electrode 122 (first electrode) is a portion of the first-substrate lower main surface S12. The signal electrode 122 is disposed on the right end portion of the lower main surface of the first substrate 12. The signal electrode 122 has a rectangular shape as viewed in the upward-downward direction.

The ground electrode 124 (first electrode) is a portion of the first-substrate lower main surface S12. The ground electrode 124 is disposed on the right end portion of the lower main surface of the body 120. The ground electrode 124 has a rectangular frame shape as viewed in the upward-downward direction. The ground electrode 124 surrounds the signal electrode 122 as viewed in the upward-downward direction.

The first signal conductor layer 128 extends through the body 120 in the leftward-rightward direction. The first signal conductor layer 128 is electrically coupled to the signal electrode 122 (first electrode). The right end portion of the first signal conductor layer 128 is electrically coupled to the signal electrode 122 through an interlayer coupling conductor (not illustrated). The interlayer coupling conductor is, for example, a via-hole conductor or a through-hole conductor.

In addition, the first substrate 12 further includes a first upper ground conductor layer and a first lower ground conductor layer (not illustrated). The first upper ground conductor layer extends in the leftward-rightward direction. The first upper ground conductor layer is disposed in the body 120. Thus, the first upper ground conductor layer is disposed over the first signal conductor layer 128. Here, in the present specification, “the first upper ground conductor layer is disposed over the first signal conductor layer 128” refers to the following situation. At least a portion of the first upper ground conductor layer is disposed in a region through which the first signal conductor layer 128 passes when translated upward. Thus, the first upper ground conductor layer may be located within the region through which the first signal conductor layer 128 passes when translated upward or may protrude from the region through which the first signal conductor layer 128 passes when translated upward. In this preferred embodiment, the first upper ground conductor layer protrudes from the region through which the first signal conductor layer 128 passes when translated upward. The first upper ground conductor layer is electrically coupled to the ground electrode 124. The right end portion of the first upper ground conductor layer is electrically coupled to the ground electrode 124 through an interlayer coupling conductor (not illustrated). The interlayer coupling conductor is, for example, a via-hole conductor or a through-hole conductor.

The first lower ground conductor layer extends in the leftward-rightward direction. The first lower ground conductor layer is disposed in the body 120 or on the lower main surface of the body 120. Thus, the first lower ground conductor layer is disposed under the first signal conductor layer 128. The first lower ground conductor layer is electrically coupled to the ground electrode 124. The right end portion of the first lower ground conductor layer is electrically coupled to the ground electrode 124 through an interlayer coupling conductor (not illustrated). The interlayer coupling conductor is, for example, a via-hole conductor or a through-hole conductor. The first signal conductor layer 128, the first upper ground conductor layer, and the first lower ground conductor layer as described above have a stripline structure. The signal electrode 122, the ground electrode 124, the first signal conductor layer 128, the first upper ground conductor layer, and the first lower ground conductor layer as described above are formed, for example, by patterning a metal foil such as a copper foil.

As illustrated in FIG. 3, the resist layer 126 is disposed on the lower main surface of the body 120. As illustrated in FIGS. 2 and 3, the resist layer 126 has openings. Thus, the signal electrode 122 and the ground electrode 124 are exposed to the outside from the resist layer 126 on the first-substrate lower main surface S12 of the first substrate 12. However, as illustrated in FIG. 3, the signal electrode 122 and the ground electrode 124 are recessed upward from the lower main surface of the resist layer 126.

The second substrate 14 extends in the forward-backward direction (a second direction orthogonal to the upward-downward direction and different from the first direction). The second substrate 14 has a plate shape. Therefore, the second substrate 14 has a second-substrate upper main surface S21 and a second-substrate lower main surface S22.

As illustrated in FIGS. 2 and 3, the second substrate 14 includes a body 140, a signal electrode 142, a ground electrode 144, a resist layer 146, and a second signal conductor layer 148. The body 140 has a structure including a plurality of insulator layers stacked together in the upward-downward direction. The body 140 is formed of an insulating material. The insulating material for the body 140 is, for example, a liquid crystal polymer (LCP) or polyimide. Therefore, the insulating material for the body 120 of the first substrate 12 is identical to the insulating material for the body 140 of the second substrate 14.

The signal electrode 142 (second electrode) is a portion of the second-substrate upper main surface S21. The signal electrode 142 is disposed on the front end portion of the upper main surface of the body 140. The signal electrode 142 has a rectangular shape as viewed in the upward-downward direction.

The ground electrode 144 (second electrode) is a portion of the second-substrate upper main surface S21. The ground electrode 144 is disposed on the front end portion of the upper main surface of the body 140. The ground electrode 144 has a rectangular frame shape as viewed in the upward-downward direction. The ground electrode 144 surrounds the signal electrode 142 as viewed in the upward-downward direction.

The second signal conductor layer 148 extends through the body 140 in the forward-backward direction. The second signal conductor layer 148 is electrically coupled to the signal electrode 142 (second electrode). The front end portion of the second signal conductor layer 148 is electrically coupled to the signal electrode 142 through an interlayer coupling conductor (not illustrated). The interlayer coupling conductor is, for example, a via-hole conductor or a through-hole conductor.

In addition, the second substrate 14 further includes a second upper ground conductor layer and a second lower ground conductor layer (not illustrated). The second upper ground conductor layer extends in the forward-backward direction. The second upper ground conductor layer is disposed in the body 140 or on the upper main surface of the body 140. Thus, the second upper ground conductor layer is disposed over the second signal conductor layer 148. The second upper ground conductor layer is electrically coupled to the ground electrode 144. The front end portion of the second upper ground conductor layer is electrically coupled to the ground electrode 144 through an interlayer coupling conductor (not illustrated). The interlayer coupling conductor is, for example, a via-hole conductor or a through-hole conductor.

The second lower ground conductor layer extends in the forward-backward direction. The second lower ground conductor layer is disposed in the body 140 or on the lower main surface of the body 140. Thus, the second lower ground conductor layer is disposed under the second signal conductor layer 148. The second lower ground conductor layer is electrically coupled to the ground electrode 144. The front end portion of the second lower ground conductor layer is electrically coupled to the ground electrode 144 through an interlayer coupling conductor (not illustrated). The interlayer coupling conductor is, for example, a via-hole conductor or a through-hole conductor. The second signal conductor layer 148, the second upper ground conductor layer, and the second lower ground conductor layer as described above have a stripline structure. The signal electrode 142, the ground electrode 144, the second signal conductor layer 148, the second upper ground conductor layer, and the second lower ground conductor layer as described above are formed, for example, by patterning a metal foil such as a copper foil.

As illustrated in FIG. 3, the resist layer 146 is disposed on the upper main surface of the body 140. As illustrated in FIGS. 2 and 3, the resist layer 146 has openings. Thus, the signal electrode 142 and the ground electrode 144 are exposed to the outside from the resist layer 146 on the second-substrate upper main surface S21 of the second substrate 14. However, as illustrated in FIG. 3, the signal electrode 142 and the ground electrode 144 are recessed downward from the upper main surface of the resist layer 146.

The interposer 16 is an anisotropic conductive film. As illustrated in FIG. 3, the interposer 16 couples together the first substrate 12 and the second substrate 14. As illustrated in FIG. 4, the interposer 16 includes a resin layer 18 and a plurality of metal members 20. The resin layer 18 has a plate shape. The resin layer 18 has a rectangular shape as viewed in the upward-downward direction. As illustrated in FIG. 2, the resin layer 18 has a resin-layer upper main surface S1 and a resin-layer lower main surface S2. The resin-layer upper main surface S1 is joined to the first-substrate lower main surface S12. More precisely, the resin-layer upper main surface S1 is joined to the right end portion of the first-substrate lower main surface S12. The resin-layer lower main surface S2 is joined to the second-substrate upper main surface S21. More precisely, the resin-layer lower main surface S2 is joined to the front end portion of the second-substrate upper main surface S21. Thus, the resin layer 18 functions as an adhesive.

In addition, as illustrated in FIG. 3, the resin layer 18 extends into recesses formed in the first-substrate lower main surface S12. Therefore, the resin layer 18 is in contact with the signal electrode 122 and the ground electrode 124. The resin layer 18 extends into recesses formed in the second-substrate upper main surface S21. Therefore, the resin layer 18 is in contact with the signal electrode 142 and the ground electrode 144.

The type of material for the resin layer 18 is identical to the type of insulating material for the body 120 of the first substrate 12 and the type of insulating material for the body 140 of the second substrate 14. The material for the resin layer 18 has a lower melting point than the insulating material for the body 120 of the first substrate 12 and the insulating material for the body 140 of the second substrate 14. The material for the resin layer 18 is, for example, a thermoplastic resin such as a liquid crystal polymer (LCP) or polyimide. However, the thermoplastic resin such as a liquid crystal polymer or polyimide for the resin layer 18 preferably has a lower melting point than the thermoplastic resin such as a liquid crystal polymer or polyimide for the body 120 of the first substrate 12 and the thermoplastic resin such as a liquid crystal polymer or polyimide for the body 140 of the second substrate 14.

Next, the plurality of metal members 20 will be described. The shape of the plurality of metal members 20 in the interposer 16 coupling together the first substrate 12 and the second substrate 14 differs from the shape of the plurality of metal members 20 in the interposer 16 not coupling together the first substrate 12 and the second substrate 14. First, the plurality of metal members 20 in the interposer 16 not coupling together the first substrate 12 and the second substrate 14 will be described.

As illustrated in FIG. 4, the plurality of metal members 20 are disposed in the resin layer 18 so as to be separated from each other. As illustrated in FIG. 4, the plurality of metal members 20 are distributed over the entire resin layer 18 as viewed in the upward-downward direction. In this preferred embodiment, the plurality of metal members 20 are arranged in a matrix. The distance d2 between adjacent ones of the plurality of metal members 20 in the leftward-rightward direction is equal or substantially equal to the distance d3 between adjacent ones of the plurality of metal members 20 in the forward-backward direction. The distances d2 and d3 between adjacent ones of the plurality of metal members 20 are greater than the dimension d1 of the plurality of metal members 20 in the upward-downward direction. Therefore, the minimum distance between adjacent ones of the plurality of metal members 20 is greater than the dimension d1 of the plurality of metal members 20 in the upward-downward direction. The arrangement of the plurality of metal members 20 in the interposer 16 coupling together the first substrate 12 and the second substrate 14 is substantially identical to the arrangement of the plurality of metal members 20 in the interposer 16 not coupling together the first substrate 12 and the second substrate 14.

As illustrated in FIGS. 4 and 5, the plurality of metal members 20 have a pillar shape extending in the upward-downward direction. More precisely, as illustrated in the enlarged view in FIG. 3, the plurality of metal members 20 have a pointed upper end portion and a pointed lower end portion. In addition, the upper portions of the plurality of metal members 20 are tapered from bottom to top. The lower portions of the plurality of metal members 20 are tapered from top to bottom. The dimension d1 of the plurality of metal members 20 in the upward-downward direction is greater than the dimension d4 of the plurality of metal members 20 in the leftward-rightward direction (the dimension in a direction orthogonal to the upward-downward direction) and the dimension d5 of the plurality of metal members 20 in the forward-backward direction (the dimension in a direction orthogonal to the upward-downward direction). Furthermore, the dimension d1 of the plurality of metal members 20 in the upward-downward direction is greater than half the thickness of the resin layer 18 in the upward-downward direction. In this preferred embodiment, as illustrated in FIG. 4, the plurality of metal members 20 extend between the resin-layer upper main surface S1 and the resin-layer lower main surface S2 in the upward-downward direction. Therefore, the dimension d1 of the plurality of metal members 20 in the upward-downward direction is equal or substantially equal to the thickness of the resin layer 18 in the upward-downward direction.

As illustrated in FIG. 5, the plurality of metal members 20 include a core 22 and a surface layer 24. The core 22 has a pillar shape extending in the upward-downward direction. The material for the core 22 has a higher Vickers hardness than the material for the signal electrodes 122 and 142 (first and second electrodes) and the material for the ground electrodes 124 and 144 (first and second electrodes). The material for the core 22 is, for example, SUS (steel use stainless). The surface layer 24 covers the surface of the core 22. In this preferred embodiment, the surface layer 24 covers the entire surface of the core 22. The material for the surface layer 24 has a higher ductility than the material for the core 22. The material for the surface layer 24 is, for example, gold.

Next, the plurality of metal members 20 in the interposer 16 coupling together the first substrate 12 and the second substrate 14 will be described. As illustrated in FIG. 3, at least some of the plurality of metal members 20 are inserted into the signal electrode 122 (first electrode) without chemical bonding with the signal electrode 122 (first electrode) and are inserted into the signal electrode 142 (second electrode) without chemical bonding with the signal electrode 142 (second electrode) to electrically couple together the signal electrode 122 (first electrode) and the signal electrode 142 (second electrode). In addition, as illustrated in FIG. 3, at least some of the plurality of metal members 20 are inserted into the ground electrode 124 (first electrode) without chemical bonding with the ground electrode 124 (first electrode) and are inserted into the ground electrode 144 (second electrode) without chemical bonding with the ground electrode 144 (second electrode) to electrically couple together the ground electrode 124 (first electrode) and the ground electrode 144 (second electrode). “Chemical bonding” in the present specification includes covalent bonding, coordinate bonding, ionic bonding, and metallic bonding. “Without chemical bonding” in the present specification refers to a situation where two members are separable upon removal of stress. That is, “without chemical bonding” in the present specification refers to a situation where two members are not joined together.

In addition, at least some of the plurality of metal members 20 are elastically deformed to apply an upward force to the signal electrode 122 (first electrode) and to apply a downward force to the signal electrode 142 (second electrode). In addition, at least some of the plurality of metal members 20 are elastically deformed to apply an upward force to the ground electrode 124 (first electrode) and to apply a downward force to the ground electrode 144 (second electrode). Thus, at least some of the plurality of metal members 20 have a curved shape. Specifically, as illustrated in FIG. 3, each of at least some of the plurality of metal members 20 has a shape in which the center of the metal member 20 in the upward-downward direction is displaced relative to the upper end of the metal member 20 and the lower end of the metal member 20 in the forward-backward direction and/or the leftward-rightward direction.

As described above, at least some of the plurality of metal members 20 are elastically deformed. Thus, when the first substrate 12 or the second substrate 14 is removed from the interposer 16, at least some of the plurality of metal members 20 return to the pillar shape extending in the upward-downward direction as illustrated in FIG. 4. Therefore, a checker checks whether or not at least some of the plurality of metal members 20 are elastically deformed by removing the first substrate 12 or the second substrate 14 from the interposer 16. Plastic deformation may remain in at least some of the plurality of metal members 20 after the checker removes the first substrate 12 or the second substrate 14 from the interposer 16. That is, at least some of the plurality of metal members 20 may be slightly curved after the checker removes the first substrate 12 or the second substrate 14 from the interposer 16.

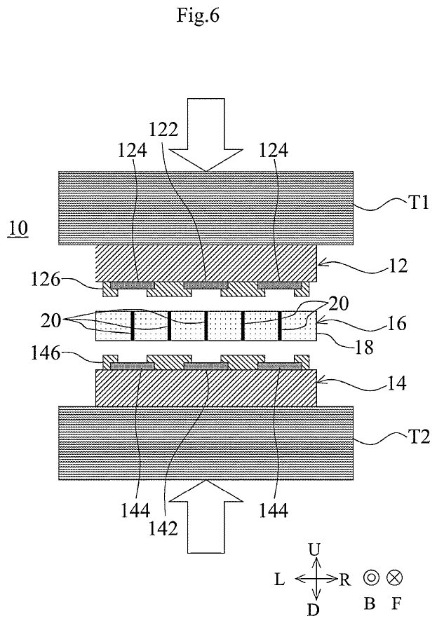

The above substrate module 10 is fabricated by the following process. FIG. 6 is a sectional view of the substrate module 10 during fabrication.

First, as illustrated in FIG. 6, the right end portion of the first substrate 12, the interposer 16, and the front end portion of the second substrate 14 are stacked together in the following order from top to bottom: the right end portion of the first substrate 12, the interposer 16, and the front end portion of the second substrate 14.

Next, the first substrate 12 is pressed downward while being heated with a tool T1, and the second substrate 14 is pressed upward while being heated with a tool T2. Thus, the resin layer 18 is heated and softened. The resin layer 18 enters the recesses in the first-substrate lower main surface S12 and enters the recesses in the second-substrate upper main surface S21. As illustrated in FIG. 3, at least some of the plurality of metal members 20 are inserted into the signal electrode 122 (first electrode) without chemical bonding with the signal electrode 122 (first electrode) and are inserted into the signal electrode 142 (second electrode) without chemical bonding with the signal electrode 142 (second electrode). In addition, as illustrated in FIG. 3, at least some of the plurality of metal members 20 are inserted into the ground electrode 124 (first electrode) without chemical bonding with the ground electrode 124 (first electrode) and are inserted into the ground electrode 144 (second electrode) without chemical bonding with the ground electrode 144 (second electrode).

Finally, the substrate module 10 is cooled to solidify the resin layer 18. Thus, the substrate module 10 is finished.

### Advantages

The interposer 16 allows the signal electrode 122 of the first substrate 12 and the signal electrode 142 of the second substrate 14 to be easily coupled together. More specifically, it may be difficult to electrically couple together a first electrode and a second electrode using the anisotropic conductive film described in Japanese Unexamined Patent Application Publication No. 2020-53403. More specifically, there are cases where the first electrode is recessed from the lower main surface of the first substrate. Similarly, there are cases where the second electrode is recessed from the upper main surface of the second substrate. In such cases, insufficient pressure may be applied between the first electrode and the second electrode. This may result in the conductive particles not being held between the first electrode and the second electrode.

Accordingly, the dimension of the plurality of metal members 20 of the interposer 16 in the upward-downward direction is greater than the dimension of the plurality of metal members 20 in a direction orthogonal to the upward-downward direction. In addition, the dimension of the plurality of metal members 20 in the upward-downward direction is greater than half the thickness of the resin layer 18 in the upward-downward direction. Thus, the interposer 16 includes a plurality of metal members 20 having a shape that is greater in the upward-downward direction instead of conductive particles. As a result, as illustrated in FIG. 3, at least some of the plurality of metal members 20 are inserted into the signal electrode 122 (first electrode) without chemical bonding with the signal electrode 122 (first electrode) and are inserted into the signal electrode 142 (second electrode) without chemical bonding with the signal electrode 142 (second electrode). Therefore, the metal members 20 can electrically couple together the signal electrode 122 and the signal electrode 142 even if insufficient pressure is applied between the signal electrode 122 and the signal electrode 142. Thus, the interposer 16 allows the signal electrode 122 of the first substrate 12 and the signal electrode 142 of the second substrate 14 to be easily coupled together. For the same reason, the interposer 16 allows the ground electrode 124 of the first substrate 12 and the ground electrode 144 of the second substrate 14 to be easily coupled together.

The interposer 16 allows the signal electrode 122 of the first substrate 12 and the signal electrode 142 of the second substrate 14 to be easily coupled together. More specifically, at least some of the plurality of metal members 20 are elastically deformed. Thus, at least some of the plurality of metal members 20 apply an upward force to the signal electrode 122 and apply a downward force to the signal electrode 142. Therefore, at least some of the plurality of metal members 20 come into contact with the signal electrode 122 more reliably. At least some of the plurality of metal members 20 come into contact with the signal electrode 142 more reliably. As a result, the interposer 16 allows the signal electrode 122 of the first substrate 12 and the signal electrode 142 of the second substrate 14 to be easily coupled together. For the same reason, the interposer 16 allows the ground electrode 124 of the first substrate 12 and the ground electrode 144 of the second substrate 14 to be easily coupled together.

The interposer 16 is less likely to damage the first substrate 12 in the step of pressure-bonding together the first substrate 12 and the interposer 16. More specifically, the material for the resin layer 18 has a lower melting point than the insulating material for the body 120 of the first substrate 12. This makes it easier to soften the first substrate 12 while inhibiting softening of the resin layer 18. As a result, the first substrate 12 is less likely to be damaged.

The plurality of metal members 20 of the interposer 16 are distributed over the entire resin layer 18 as viewed in the upward-downward direction. Thus, substrates with various electrode layouts can be joined together. As a result, the interposer 16 has high versatility.

The interposer 16 allows the signal electrode 122 of the first substrate 12 and the signal electrode 142 of the second substrate 14 to be easily coupled together. More specifically, the material for the core 22 has a higher Vickers hardness than the material for the signal electrodes 122 and 142 and the material for the ground electrodes 124 and 144. Thus, the metal members 20 are easily inserted into the signal electrodes 122 and 142 and the ground electrodes 124 and 144. As a result, the interposer 16 allows the signal electrode 122 of the first substrate 12 and the signal electrode 142 of the second substrate 14 to be easily coupled together.

The insulating material for the body 120 of the first substrate 12 for use with the interposer 16 is identical to the insulating material for the body 140 of the second substrate 14. Thus, the coefficient of linear expansion of the insulating material for the body 120 of the first substrate 12 is equal to the coefficient of linear expansion of the insulating material for the body 140 of the second substrate 14. Therefore, when the substrate module 10 is heated, the amount of thermal deformation of the first substrate 12 is close to the amount of thermal deformation of the second substrate 14. As a result, the substrate module 10 is less likely to warp.

The type of material for the resin layer 18 of the interposer 16 is identical to the type of insulating material for the body 120 of the first substrate 12. Thus, the resin layer 18 and the first substrate 12 are firmly bonded together. For the same reason, the resin layer 18 and the second substrate 14 are firmly bonded together.

The interposer 16 allows the manufacturing cost of the substrate module 10 to be reduced. More specifically, when an L-shaped substrate is fabricated, it is contemplated that, for example, a resin sheet is punched into an L shape. In this case, however, a wasted region that is not used as a substrate occurs in the resin sheet. As a result, the manufacturing cost of an L-shaped substrate tends to be higher.

Accordingly, the first substrate 12 extends in the leftward-rightward direction (a first direction orthogonal to the upward-downward direction). The second substrate 14 extends in the forward-backward direction (a second direction orthogonal to the upward-downward direction and different from the first direction). Thus, the interposer 16 couples together the straight first substrate 12 and the straight second substrate 14 to form the L-shaped substrate module 10. When the straight first substrate 12 and second substrate 14 are fabricated, a smaller wasted region that is not used as a substrate occurs in the resin sheet. As a result, the manufacturing cost of the substrate module 10 is reduced.

The plurality of metal members 20 extend between the resin-layer upper main surface S1 and the resin-layer lower main surface S2 in the upward-downward direction. Thus, the metal members 20 are easily inserted into the signal electrodes 122 and 142 and the ground electrodes 124 and 144. As a result, the interposer 16 allows the signal electrode 122 of the first substrate 12 and the signal electrode 142 of the second substrate 14 to be easily coupled together.

The plurality of metal members 20 have a pillar shape extending in the upward-downward direction. Thus, the plurality of metal members 20 are easily elastically deformed when subjected to a force in the upward-downward direction. As a result, the interposer 16 allows the signal electrode 122 of the first substrate 12 and the signal electrode 142 of the second substrate 14 to be easily coupled together.

The distances d2 and d3 between adjacent ones of the plurality of metal members 20 are greater than the dimension d1 of the plurality of metal members 20 in the upward-downward direction. Thus, when the metal members 20 are tilted in the forward-backward direction or the leftward-rightward direction, adjacent metal members 20 are less likely to come into contact with each other. As a result, the metal members 20 are less likely to be short-circuited to each other.

### Other Preferred Embodiments

Interposers according to preferred embodiments of the present invention are not limited to the interposer 16, but can be changed within the spirit thereof.

At least some of the plurality of metal members 20 of the interposer 16 may be plastically deformed. However, at least some of the plurality of metal members 20 are elastically deformed even if there is plastic deformation.

The melting point of the material for the resin layer 18 of the interposer 16 may be higher than or equal to the melting point of the insulating material for the body 120 of the first substrate 12 or the melting point of the insulating material for the body 140 of the second substrate 14.

The plurality of metal members 20 of the interposer 16 may be distributed within a portion of the resin layer 18, rather than over the entire resin layer 18, as viewed in the upward-downward direction. In addition, the plurality of metal members 20 need not be arranged in a matrix, but may be arranged in, for example, a staggered manner. Alternatively, the plurality of metal members 20 may be irregularly arranged.

The Vickers hardness of the material for the core 22 of the interposer 16 may be lower than or equal to the Vickers hardness of the material for the signal electrodes 122 and 142 (first and second electrodes) or the Vickers hardness of the material for the ground electrodes 124 and 144 (first and second electrodes).

The surface layer 24 is not an essential element for the interposer 16. In addition, the ductility of the material for the surface layer 24 may be lower than or equal to the ductility of the material for the core 22.

The insulating material for the body 120 of the first substrate 12 for use with the interposer 16 may be different from the insulating material for the body 140 of the second substrate 14.

The type of material for the resin layer 18 of the interposer 16 need not be identical to the type of insulating material for the body 120 of the first substrate 12 and/or the type of insulating material for the body 140 of the second substrate 14.

The first substrate 12 and the second substrate 14 for use with the interposer 16 need not extend in a straight line. In addition, the direction in which the first substrate 12 extends may be identical to the direction in which the second substrate 14 extends. In addition, the direction in which the first substrate 12 extends need not be orthogonal to the direction in which the second substrate 14 extends.

The plurality of metal members 20 of the interposer 16 need not extend between the resin-layer upper main surface S1 and the resin-layer lower main surface S2 in the upward-downward direction.

The plurality of metal members 20 of the interposer 16 may have a shape other than a pillar shape extending in the upward-downward direction.

The distance between adjacent ones of the plurality of metal members 20 of the interposer 16 may be smaller than or equal to the dimension of the plurality of metal members 20 in the upward-downward direction.

The material for the core 22 of the interposer 16 is not limited to SUS. The material for the core 22 may be, for example, phosphor bronze or beryllium copper.

The insulating material for the resin layer 18 may be, for example, a thermosetting polyurethane. In this case, the type of material for the resin layer 18 is not identical to the type of insulating material for the body 120 of the first substrate 12 or the type of insulating material for the body 140 of the second substrate 14. The thermal deformation temperature of the thermosetting polyurethane is preferably lower than the melting point of the insulating material for the body 120 of the first substrate 12 and the melting point of the insulating material for the body 140 of the second substrate 14. When the first substrate 12 is pressed downward while being heated with the tool T1, and the second substrate 14 is pressed upward while being heated with the tool T2, a thermosetting reaction proceeds, thus curing the resin layer 18.

The material for the resin layer 18 may be identical to the insulating material for the body 120 of the first substrate 12 and the insulating material for the body 140 of the second substrate 14.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An interposer to couple together a first substrate and a second substrate, the first substrate including a first-substrate upper main surface and a first-substrate lower main surface and including a first electrode that is a portion of the first-substrate lower main surface, the second substrate including a second-substrate upper main surface and a second-substrate lower main surface and including a second electrode that is a portion of the second-substrate upper main surface, the interposer comprising:
a resin layer including a resin-layer upper main surface to be joined to the first-substrate lower main surface and a resin-layer lower main surface to be joined to the second-substrate upper main surface; and
a plurality of metal bodies in the resin layer and separated from each other, a dimension of each of the plurality of metal bodies in an upward-downward direction being greater than a dimension of each of the plurality of metal bodies in a direction orthogonal to the upward-downward direction; wherein
at least one of the plurality of metal bodies is located in the first electrode and at least one of the plurality of metal bodies is located in the second electrode to electrically couple together the first electrode and the second electrode.

2. The interposer according to claim 1, wherein at least some of the plurality of metal bodies are elastically deformed to apply an upward force to the first electrode and to apply a downward force to the second electrode.

3. The interposer according to claim 1, wherein a material for the resin layer has a lower melting point than an insulating material for a body of the first substrate and an insulating material for a body of the second substrate.

4. The interposer according to claim 1, wherein the plurality of metal bodies are distributed over an entirety of the resin layer as viewed in the upward-downward direction.

5. The interposer according to claim 1, wherein
each of the metal bodies includes a core; and
a material for the core has a higher Vickers hardness than a material for the first electrode and a material for the second electrode.

6. The interposer according to claim 1, wherein
each of the metal bodies includes a core and a surface layer covering a surface of the core; and
a material for the surface layer has a higher ductility than a material for the core.

7. The interposer according to claim 1, wherein an insulating material for a body of the first substrate is identical to an insulating material for a body of the second substrate.

8. The interposer according to claim 1, wherein a type of material for the resin layer is identical to a type of insulating material for a body of the first substrate.

9. The interposer according to claim 1, wherein at least one of the plurality of metal bodies is inserted into the first electrode without chemical bonding with the first electrode and at least one of the plurality of metal bodies is inserted into the second electrode without chemical bonding.

10. A substrate module comprising:
the interposer according to claim 1;
the first substrate; and
the second substrate.

11. The substrate module according to claim 10, wherein
the first substrate further includes a first signal conductor layer electrically coupled to the first electrode; and
the second substrate further includes a second signal conductor layer electrically coupled to the second electrode.

12. The substrate module according to claim 11, wherein
the first substrate extends in a first direction orthogonal to the upward-downward direction; and
the second substrate extends in a second direction orthogonal to the upward-downward direction and different from the first direction.

13. An interposer comprising:
a resin layer; and
a plurality of metal bodies in the resin layer and separated from each other, a dimension of each of the plurality of metal bodies in an upward-downward direction being greater than a dimension of each of the plurality of metal bodies in a direction orthogonal to the upward-downward direction and about one half of a thickness of the resin layer in the upward-downward direction.

14. The interposer according to claim 13, wherein the plurality of metal bodies extend between an resin-layer upper main surface and an resin-layer lower main surface of the resin layer in the upward-downward direction.

15. The interposer according to claim 13, wherein each of the plurality of metal bodies has a pillar shape extending in the upward-downward direction.

16. The interposer according to claim 13, wherein a distance between adjacent ones of the plurality of metal bodies is greater than the dimension of each of the plurality of metal bodies in the upward-downward direction.

17. The interposer according to claim 13, wherein at least one of the plurality of metal bodies is located in a first electrode and at least one of the plurality of metal bodies is located in a second electrode to electrically couple together the first electrode and the second electrode.

18. The interposer according to claim 13, wherein at least some of the plurality of metal bodies are elastically deformed to apply an upward force to the first electrode and to apply a downward force to the second electrode.

19. The interposer according to claim 13, wherein
each of the metal bodies includes a core; and
a material for the core has a higher Vickers hardness than a material for a first electrode and a material for a second electrode.

20. The interposer according to claim 13, wherein
each of the metal bodies includes a core and a surface layer covering a surface of the core; and
a material for the surface layer has a higher ductility than a material for the core.
